(19) United States
(12) Patent Application Publication
(10) Pub. No.: US 2012/0044759 A1
(43) Pub. Date: Feb. 23, 2012

(54) NONVOLATILE SEMICONDUCTOR MEMORY DEVICE AND DRIVING METHOD THEREOF

(76) Inventor: Keita TAKAHASHI, Nara (JP)

(21) Appl. No.: 13/169,795

(22) Filed: Jun. 27, 2011

(30) Foreign Application Priority Data
Aug. 23, 2010 (JP) 2010-186202

(51) Int. Cl. G11C 11/34

(52) U.S. Cl. 365/184

(57) ABSTRACT

A nonvolatile semiconductor memory device has a first select transistor having a gate connected to a first select word line extending in a column direction, a source connected to a first sub bit line, and a drain connected to a first main bit line extending in a row direction, and a second select transistor having a gate connected to a second select word line extending in the column direction, a source connected to a second sub bit line, and a drain connected to a second main bit line extending in the row direction. The second select transistor has a lower breakdown voltage than the first select transistor.

### CROSS-REFERENCE TO RELATED APPLICATION

This application claims priority to Japanese Patent Application No. 2010-186202 filed on Aug. 23, 2010, the disclosure of which including the specification, the drawings, and the claims is hereby incorporated by reference in its entirety.

### BACKGROUND

The present invention relates to nonvolatile semiconductor memory devices, and more particularly to nonvolatile semiconductor memory devices such as metal oxide-nitride-oxide semiconductor (MONOS) memory devices, and driving methods thereof

With recent increased integration density and reduced cost of nonvolatile semiconductor memory devices, local trap type MONOS memory devices have been proposed which have a virtual ground array and locally trap charge in an oxide-nitride-oxide (ONO) film as a gate insulating film. The use of the local trap type MONOS memory devices can effectively reduce the memory cell size as they can accumulate charge independently on both drain and source sides of each memory cell and thus can store and retain 2 bits per cell.

A conventional nonvolatile semiconductor memory device will be described below with reference to the accompanying drawings (see, e.g., U.S. Pat. No. 5,963,465).

First, wiring of a memory cell array in the conventional nonvolatile semiconductor memory device will be described below with reference to FIG. 8.

As shown in FIG. 8, a plurality of memory cells 101 are arranged in a matrix pattern (rows and columns). The source and drain of each memory cell 101 are respectively connected to the sources of corresponding ones of select transistors 103 via corresponding ones of sub bit lines 102 extending in an X direction (a row direction). The drain of each select transistor 103 is connected to a corresponding one of main bit lines 104 extending in the X direction, and the gate of each select transistor 103 is connected to a corresponding one of select word lines 106 extending in a Y direction (a column direction). A gate electrode of each memory cell 101 is connected to a corresponding one of memory word lines 105 extending in the Y direction.

High breakdown voltage transistors are used as the select transistors 103 so that the select transistors 103 can be driven at a voltage of up to about 10 V that is applied in a write operation. A gate oxide film of each select transistor 103 has a thickness of about 20 nm, and a gate length of each select transistor 103 is about 0.7 μm.

Note that as shown by, e.g., a first rewrite sector A and a second rewrite sector B, a rewrite unit of retained data is a group of memory cells 101 that are included in a region interposed between the select transistors 103 and that are in a range that is rewritten by a series of rewrite operations.

In the following description, the “drain” of each memory cell 101 refers to a terminal that serves as a drain when writing a first bit of the memory cell. Similarly, the “source” of each memory cell 101 refers to a terminal that serves as a source when writing the first bit of the memory cell. That is, although the function of each terminal is actually reversed depending on the bit to be written (i.e., each terminal actually serves either as a physical drain or a physical source depending on the bit to be written), the drain and the source are herein fixed as described above for convenience of description.

A method of writing data in a first bit of a cell to be written will be described below with reference to FIG. 9.

As shown in FIG. 9, the cell to be written is the first bit of the circled memory cell 101 connected to WL1 of the memory word lines 105. A voltage of 10 V is applied to WL1, a voltage of 10 V is applied to SWL1 and SWL2 of the select word lines 106, a voltage of 5 V is applied to MBL1 of the main bit lines 104, and a voltage of 0 V is applied to the remaining terminals. Thus, the voltage of 10 V is applied to the gate of the designated memory cell 101, the voltage of 5 V is applied to the drain thereof, and the voltage of 0 V is applied to the source thereof. As a result, channel hot electrons are generated at the drain end, and the electrons are trapped at the drain end of the ONO film of the memory cell 101. Thus, the threshold voltage of the first bit of the memory cell 101 increases from about 2 V in an erased state to about 6 V in a written state.

A method of writing data in a second bit of a cell to be written will be described below with reference to FIG. 10.

As shown in FIG. 10, the cell to be written is the second bit of the circled memory cell 101 connected to WL1 of the memory word lines 105. A voltage of 10 V is applied to WL1, a voltage of 10 V is applied to SWL1 and SWL2 of the select word lines 106, a voltage of 5 V is applied to MBL2 of the main bit lines 104, and a voltage of 0 V is applied to the remaining terminals. Thus, the voltage of 10 V is applied to the gate of the designated memory cell 101, the voltage of 5 V is applied to the source thereof, and the voltage of 0 V is applied to the drain thereof. As a result, channel hot electrons are generated at the source end, and the electrons are trapped at the source end of the ONO film of the memory cell 101. Thus, the threshold voltage of the second bit of the memory cell 101 increases from about 2 V in the erased state to about 6 V in the written state.

By performing the above procedures, data is written to the memory cells 101 included in the first rewrite sector A that is interposed between the select transistors 103 respectively connected to the upstream and downstream sides of the main bit lines 104. The sub bit lines 102 connected to the memory cells 101 included in the first rewrite sector A are electrically isolated from the second rewrite sector B by the two select transistors 103. Thus, in the write operation, the voltage of 5 V that is applied to the drain or source of the memory cell 101 to be rewritten is not applied to the sub bit lines 102 in the second rewrite sector B. Accordingly, the state of each memory cell 101 included in the second rewrite sector B does not change when writing the memory cells 101 in the first rewrite sector A. That is, it is ensured that the memory cells 101 in the second rewrite sector B do not change from the erased state to the written state or from the written state to the erased state.

A method of erasing data of the first bits of cells to be erased will be described below with reference to FIG. 11. As shown in FIG. 11, the memory cells 101 to be erased are the first bits of the circled memory cells 101 connected to WL0 to WL2 of the memory word lines 105. A voltage of −5 V is applied to WL0 to WL2, a voltage of 10 V is applied to SWL0 and SWL1 of the select word lines 106, a voltage of 5 V is applied to MBL1 and MBL3 of the main bit lines 104, and a voltage of 0 V is applied to the remaining terminals. Thus, the voltage of −5 V is applied to the gates of the memory cells 101 included in the first rewrite sector A, the voltage of 5 V is applied to the drains thereof, and the sources thereof are in an open state. As a result, a band-to-band tunneling current is generated at the drain end of each memory cell 101, and holes are trapped at the drain end of the ONO film of each memory cell 101. Accordingly, the threshold voltage of the first bit of each memory cell 101 decreases from about 6 V in the written state to about 2 V in the erased state.

A method of erasing data of the second bits of cells to be erased will be described below with reference to FIG. 12.

As shown in FIG. 12, the memory cells 101 to be erased are the second bits of the circled memory cells 101 connected to WL0 to WL2 of the memory word lines 105. A voltage of −5 V is applied to WL0 to WL2, a voltage of 10 V is applied to SWL2 and SWL3 of the select word lines 106, a voltage of 5 V is applied to MBL0, MBL2, and MBL4 of the main bit lines 104, and a voltage of 0 V is applied to the remaining terminals. Thus, the voltage of −5 V is applied to the gates of the memory cells 101 included in the first rewrite sector A, the voltage of 5 V is applied to the sources thereof, and the drains thereof are in an open state. As a result, a band-to-band tunneling current is generated at the source end of each memory cell 101, and holes are trapped at the source end of the ONO film of each memory cell 101. Thus, the threshold voltage of the second bit of each memory cell 101 decreases from about 6 V in the written state to about 2 V in the erased state.

By performing the above procedures, retained data is erased from the memory cells 101 included in the first rewrite sector A that is interposed between the select transistors 103 respectively connected to the upstream and downstream sides of the main bit lines 104. The sub bit lines 102 connected to the memory cells 101 included in the first rewrite sector A are electrically isolated from the second rewrite sector B by the select transistors 103. Thus, in the erase operation, the voltage of 5 V that is applied to the drains or sources of the memory cells 101 to be erased is not applied to the sub bit lines 102 in the second rewrite sector B. Accordingly, it is ensured that the state of each memory cell 101 included in the second rewrite sector B does not change when erasing the memory cells 101 in the first rewrite sector A.

A method of reading data of the first bit of a cell to be read will be described below with reference to FIG. 13.

As shown in FIG. 13, the memory cell 101 to be read is the first bit of the circled memory cell 101 connected to WL1 of the memory word lines 105. A voltage of 5 V is applied to WL1, a voltage of 5 V is applied to SWL1 and SWL2 of the select word lines 106, a voltage of 1 V is applied to MBL2 of the main bit lines 104, and a voltage of 0 V is applied to the remaining terminals. Thus, the voltage of 5 V is applied to the gate of the designated memory cell 101, the voltage of 1 V is applied to the source thereof, and the voltage of 0 V is applied to the drain thereof, whereby a channel current flows from the source to the drain.

The channel current that flows in the read operation is about 20 μA in the erased state (the threshold voltage is about 2 V) where holes are trapped at the drain end of the ONO film, but is less than 1 μA in the written state (the threshold voltage is about 6 V) where electrons are trapped at the drain end of the ONO film. Thus, the retained data can be determined by the channel current.

A method of reading data of the second bit of a cell to be read will be described below with reference to FIG. 14.

As shown in FIG. 14, the memory cell 101 to be read is the second bit of the circled memory cell 101 connected to WL1 of the memory word lines 105. A voltage of 5 V is applied to WL1, a voltage of 5 V is applied to SWL1 and SWL2 of the select word lines 106, a voltage of 1 V is applied to MBL1 of the main bit lines 104, and a voltage of 0 V is applied to the remaining terminals. Thus, the voltage of 5 V is applied to the gate of the designated memory cell 101, the voltage of 0 V is applied to the source thereof, and the voltage of 1 V is applied to the drain thereof, whereby a channel current flows from the drain to the source.

By performing the above procedures, data is read from the memory cells 101 included in the first rewrite sector A that is interposed between the select transistors 103 respectively connected to the upstream and downstream sides of the main bit lines 104. The sub bit lines 102 connected to the memory cells 101 included in the first rewrite sector A are electrically isolated from the second rewrite sector B by the two select transistors 103. Thus, in the read operation, the voltage of 1 V that is applied to the drain or source of the memory cell 101 to be read is not applied to the sub bit lines 102 in the second rewrite sector B. Accordingly, it is ensured that the state of each memory cell 101 included in the second rewrite sector B does not change when reading the memory cells 101 in the first rewrite sector A.

A configuration of a conventional decoder circuit will be described below with reference to FIG. 15.

As shown in FIG. 15, the memory word lines WL0 to WL5 are connected to a word line decoder 111, the select word lines SWL0 to SWL7 are connected to a select word line decoder 112, and the main bit lines MBL0 to MBL5 are connected to a main bit line decoder 113.

Since the decoders 111, 112, and 113 need to drive a voltage of up to 10 V, the decoders 111, 112, and 113 are formed by high breakdown voltage transistors like the select transistors 103.

### SUMMARY

However, since the conventional nonvolatile semiconductor memory device retains 2-bit data per cell, phenomena occur such as a phenomenon (2^{nd} Bit Effect) in which the threshold voltage of the second bit appears to increase due to electrons written in the first bit, and a phenomenon (a soft program) in which the second bit is gradually written if the first bit is continuously read, thereby causing a reliability problem. Thus, the conventional nonvolatile semiconductor memory device is reliable enough as a general-purpose memory device, but is not reliable enough for applications of nonvolatile memory devices that are mounted on microcomputers, namely microcomputer-mounted memory applications. This is because the general-purpose memory devices need only be designed on the assumption that the read time of a certain bit is “10 years/the total number of bits/the number of bits that are read simultaneously,” while the microcomputers are designed on the assumption that the microcomputers may be used under the condition that the same bit is continuously read for 10 years. Thus, the conventional nonvolatile semiconductor memory device is not reliable enough in terms of the soft program. Another factor that affects the reliability of the conventional nonvolatile semiconductor memory device in the microcomputer-mounted applications is the read speed (access time of 20 ns, etc.) that is about twice that in the general-purpose memory devices.

One possible method to increase the reliability while making use of the features of local trap type memory cells having a small area is to limit the microcomputer-mounted memory applications to the specification in which 1-bit data is retained per cell.

However, applying this method to the conventional memory cell array results in a waste of the area in the configuration of the select transistors, because the related art is designed based on the specification in which 2-bit data is retained per cell. That is, the occupied area is increased by the plurality of select transistors, whereby efficiency of memory cell layout is reduced.

Moreover, since high breakdown voltage transistors are used as the select transistors, a high voltage needs to be applied to obtain a driving current required for a read operation. Thus, the area of a decoder for driving the high voltage and power consumption thereof are increased, and the read speed is reduced.

In view of the above problems, objects of the present invention are to implement higher efficiency of cell layout and lower current consumption in a read operation, to enable data to be read at a high speed, and to enable the area of a decoder to be reduced.

Note that the above objects need not necessarily be achieved simultaneously, and at least reduction in area of select transistors need be implemented.

In order to achieve the above objects, according to the present invention, select transistors in a nonvolatile semiconductor memory device are divided into a select transistor for a rewrite operation and a select transistor for a read operation, and a low breakdown voltage transistor having a small area is used as the select transistor for the read operation.

Specifically, a first nonvolatile semiconductor memory device according to the present invention includes: a semiconductor region; a plurality of charge trapping memory cells formed on the semiconductor region and arranged in rows and columns, and each having a first electrode, a second electrode, and a third electrode; a plurality of word lines each connecting in common the first electrodes of the plurality of memory cells arranged in a column direction; a plurality of first sub bit lines each connecting in common the second electrodes of the plurality of memory cells arranged in a row direction; a plurality of second sub bit lines each connecting in common the third electrodes of the plurality of memory cells arranged in the row direction; a first select transistor having a gate connected to a first select word line extending in the column direction, a source connected to the first sub bit line, and a drain connected to a first main bit line extending in the row direction; and a second select transistor having a gate connected to a second select word line extending in the column direction, a source connected to the second sub bit line, and a drain connected to a second main bit line extending in the row direction, wherein each of the memory cells is capable of retaining 1-bit data, and the second select transistor has a lower breakdown voltage than the first select transistor.

According to the first nonvolatile semiconductor memory device, the area occupied by the select transistors is reduced, whereby efficiency of cell layout can be increased, and current consumption in a read operation can be reduced. Moreover, data can be read at a high speed.

The first nonvolatile semiconductor memory device may further include a protective diode having one terminal connected to the second sub bit line, and the other terminal connected to a control circuit.

The first nonvolatile semiconductor memory device may further include a protective transistor having a gate and a drain both connected to the second sub bit line, and a source connected to a control circuit.

A second nonvolatile semiconductor memory device according to the present invention includes: a semiconductor region; a plurality of charge trapping memory cells formed on the semiconductor region and arranged in rows and columns, and each having a first electrode, a second electrode, and a third electrode; a plurality of word lines each connecting in common the first electrodes of the plurality of memory cells arranged in a column direction; a plurality of first sub bit lines each connecting in common the second electrodes of the plurality of memory cells arranged in a row direction; a plurality of second sub bit lines each connecting in common the third electrodes of the plurality of memory cells arranged in the row direction; a first select transistor having a gate connected to a first select word line extending in the column direction, a source connected to the first sub bit line, and a drain connected to a first main bit line extending in the row direction; a second select transistor having a gate connected to a second select word line extending in the column direction, a source connected to the second sub bit line, and a drain connected to a second main bit line extending in the row direction; a first main bit line decoder circuit including a first transistor that supplies a first voltage to the first main bit line; and a second main bit line decoder circuit including a second transistor that supplies a second voltage to the second main bit line, wherein each of the memory cells is capable of retaining 1-bit data, and the second transistor has a lower breakdown voltage than the first transistor.

According to the second nonvolatile semiconductor memory device, the area occupied by the second main bit line decoder circuit is reduced, whereby efficiency of cell layout can be increased, and current consumption in a read operation can be reduced. Moreover, data can be read at a high speed.

A third nonvolatile semiconductor memory device according to the present invention includes: a semiconductor region; a plurality of charge trapping memory cells formed on the semiconductor region and arranged in rows and columns, and each having a first electrode, a second electrode, and a third electrode; a plurality of word lines each connecting in common the first electrodes of the plurality of memory cells arranged in a column direction; a plurality of first sub bit lines each connecting in common the second electrodes of the plurality of memory cells arranged in a row direction; a plurality of second sub bit lines each connecting in common the third electrodes of the plurality of memory cells arranged in the row direction; a first select transistor having a gate connected to a first select word line extending in the column direction, a source connected to the first sub bit line, and a drain connected to a first main bit line extending in the row direction; a second select transistor having a gate connected to a second select word line extending in the column direction, a source connected to the second sub bit line, and a drain connected to a second main bit line extending in the row direction; a first select word line decoder circuit including a first transistor that supplies a first voltage to the gate of the first select transistor; and a second select word line decoder circuit including a second transistor that supplies a second voltage to the gate of the second select transistor, wherein each of the memory cells is capable of retaining 1-bit data, and the second transistor has a lower breakdown voltage than the first transistor.

According to the third nonvolatile semiconductor memory device, the area occupied by the second select word line decoder circuit is reduced, whereby efficiency of cell layout can be increased, and current consumption in a read operation can be reduced. Moreover, data can be read at a high speed.

It is preferable that the third nonvolatile semiconductor memory device further include: a first main bit line decoder circuit including a third transistor that supplies a third voltage to the first main bit line; and a second main bit line decoder circuit including a fourth transistor that supplies a fourth voltage to the second main bit line, and that the fourth transistor have a lower breakdown voltage than the third transistor.

Thus, the area occupied by the second main bit line decoder circuit is reduced, whereby efficiency of cell layout can further be increased, and current consumption in a read operation can further be reduced.

In the first to third nonvolatile semiconductor memory devices, each of the memory cells may have a gate insulating film between the semiconductor region and the first electrode, and the gate insulating film may be formed by stacking at least a silicon oxide film and a silicon nitride film, and may be capable of trapping carriers.

A method for driving the first nonvolatile semiconductor memory device including the protective diode or the protective transistor includes: outputting a ground potential from the control circuit when erasing the data that is retained in the memory cells; and outputting a potential higher than the ground potential from the control circuit when reading the data that is retained in the memory cells.

Thus, the possibility of malfunction of the second select transistor can be reduced in an erase operation.

According to the nonvolatile semiconductor memory device of the present invention, the select transistor for the read operation can be replaced with a low breakdown voltage transistor that occupies a small area. Thus, the efficiency of cell layout can be increased. Moreover, using a low breakdown voltage transistor for the decoder circuit reduces the number of high breakdown voltage transistors that are used, whereby current consumption can be reduced, and the read speed is increased.

### BRIEF DESCRIPTION OF THE DRAWINGS

FIG. 1 is a partial circuit diagram showing a memory cell array of a nonvolatile semiconductor memory device according to an example embodiment.

FIG. 2 is a partial circuit diagram illustrating a write method in the nonvolatile semiconductor memory device according to the example embodiment.

FIG. 3 is a partial circuit diagram illustrating an erase method in the nonvolatile semiconductor memory device according to the example embodiment.

FIG. 4 is a partial circuit diagram illustrating a read method in the nonvolatile semiconductor memory device according to the example embodiment.

FIG. 5 is a schematic circuit diagram, including a decoder circuit, of the nonvolatile semiconductor memory device according to the example embodiment.

FIG. 6 is a schematic circuit diagram illustrating a first protective element of the nonvolatile semiconductor memory device according to the example embodiment.

FIG. 7 is a schematic circuit diagram illustrating a second protective element of the nonvolatile semiconductor memory device according to the example embodiment.

FIG. 8 is a partial circuit diagram showing a memory cell array of a conventional nonvolatile semiconductor memory device.

FIG. 9 is a partial circuit diagram illustrating a first write method in the conventional nonvolatile semiconductor memory device.

FIG. 10 is a partial circuit diagram illustrating a second write method in the conventional nonvolatile semiconductor memory device.

FIG. 11 is a partial circuit diagram illustrating a first erase method in the conventional nonvolatile semiconductor memory device.

FIG. 12 is a partial circuit diagram illustrating a second erase method in the conventional nonvolatile semiconductor memory device.

FIG. 13 is a partial circuit diagram illustrating a first read method in the conventional nonvolatile semiconductor memory device.

FIG. 14 is a partial circuit diagram illustrating a second read method in the conventional nonvolatile semiconductor memory device.

FIG. 15 is a schematic circuit diagram, including a decoder circuit, of the conventional nonvolatile semiconductor memory device.

### DETAILED DESCRIPTION

### Example Embodiment

A nonvolatile semiconductor memory device according to an example embodiment will be described below with reference to the accompanying drawings.

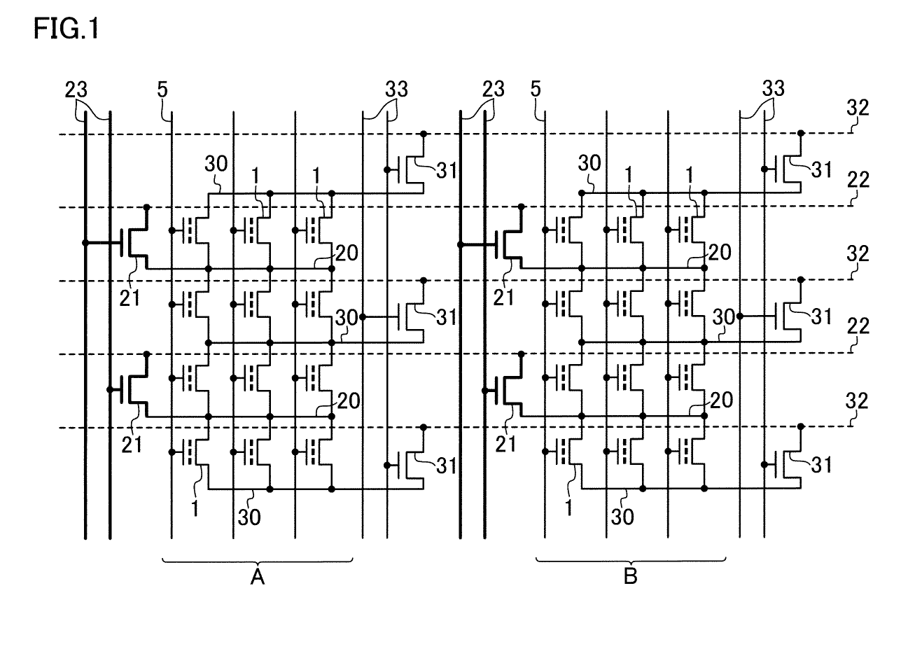

First, wiring of a memory cell array of the nonvolatile semiconductor memory device according to the example embodiment will be described below with reference to FIG. 1.

As shown in FIG. 1, the nonvolatile semiconductor memory device of the example embodiment has a semiconductor region formed by a semiconductor substrate (not shown), etc., and a plurality of memory cells 1 formed on the semiconductor region and arranged in, e.g., a matrix pattern (rows and columns). The drain of each memory cell 1 is connected to the source of a corresponding one of first select transistors 21 via a corresponding one of first sub bit lines 20 extending in an X direction (a row direction). The drain of each first select transistor 21 is connected to a corresponding one of first main bit lines 22 extending in the X direction, and the gate of each first select transistor 21 is connected to a corresponding one of first select word lines 23 extending in a Y direction (a column direction). The source of each memory cell 1 is connected to the source of a corresponding one of second select transistors 31 via a corresponding one of second sub bit lines 30 extending in the X direction. The gate of each memory cell 1 is connected to a corresponding one of memory word lines (word lines) 5. For example, although not shown in the figure, a gate insulating film having an ONO film structure in which a silicon nitride (SiN) film is vertically interposed between silicon oxide (SiO₂) films is used as a charge trapping film that is provided between the gate of each memory cell 1 or the memory word line 5 and the semiconductor region. Note that the trapping film is not limited to the ONO film, and may have any structure in which at least one layer of the SiN film is interposed between insulating films. An insulating film containing fine conductor particles having a particle size of about several nanometers, such as silicon (Si) particles, may be used instead of the SiN film.

The drain of each second select transistor 31 is connected to a corresponding one of second main bit lines 32 extending in the X direction, and the gate of each second select transistor 31 is connected to a corresponding one of second select word lines 33 extending in the Y direction. A gate electrode of each memory cell 1 is connected to a corresponding one of the memory word lines 5 extending in the Y direction.

The first select transistors 21 are high breakdown voltage transistors. For example, high breakdown voltage transistors having a gate oxide film with a thickness of about 20 nm, and having a gate length of about 0.7 μm are used so that the first select transistors 21 can be driven at a voltage of up to about 10 V that is applied in a write operation. On the other hand, the second select transistors 31 are low breakdown voltage transistors. For example, transistors having a gate insulating film with a thickness of about 3 nm, and having a gate length of about 0.18 μm can be used so as to have a breakdown voltage of about 1.8 V. Note that it is important for the low breakdown voltage transistors that are used as the second select transistors 31 to have higher mutual conductance (that allows a higher current to flow under the same voltage conditions) than the high breakdown voltage transistors that are used as the first select transistors 21. Thus, transistors having a breakdown voltage of about 5 V or transistors having a breakdown voltage of about 3 V may be used as the second select transistors 31.

Note that the drain and source of each memory cell 1 are formed by diffusion layers formed in the semiconductor region, and one of the diffusion layers functions as a drain in a write operation, and the other diffusion layer functions as a drain in a read operation. The drain and source of each select transistor 21, 31 are also formed by diffusion layers formed in the semiconductor region.

As shown by, e.g., a first rewrite sector A and a second rewrite sector B, as a rewrite unit of retained data in the plurality of memory cells 1, a group of memory cells 1 that are located in a region interposed between the first and second select transistors 21, 31 are rewritten at a time.

Thus, one feature of the example embodiment is that low breakdown voltage transistors are used as the second select transistors 31.

(Write Method)

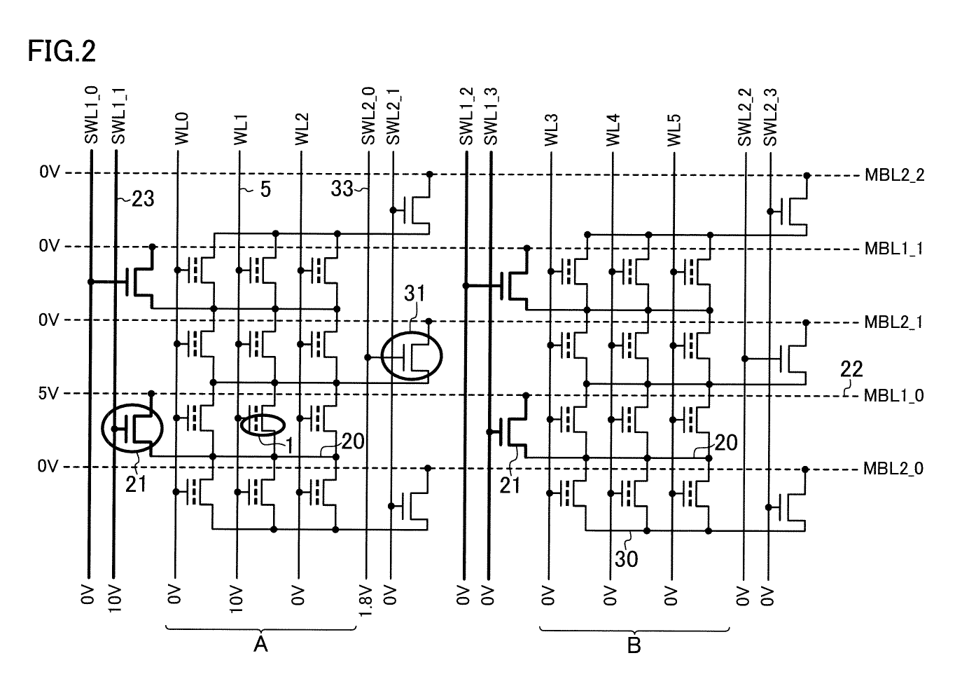

A method of writing data to a cell to be written in the first rewrite sector A will be described below with reference to FIG. 2.

As shown in FIG. 2, the cell to be written is the circled memory cell 1 that is connected to WL1 of the memory word lines 5. A voltage of 10 V is applied to WL1, a voltage of 10 V is applied to SWL1_1 of the first select word lines 23, a voltage of 1.8 V is applied to SWL2_0 of the second select word lines 33, a voltage of 5 V is applied to MBL1_0 of the first main bit lines 22, and a voltage of 0 V is applied to the remaining terminals. Thus, the voltage of 10 V is applied to the gate of the designated memory cell 1, the voltage of 5 V is applied to the drain thereof, and the voltage of 0 V is applied to the source thereof

Accordingly, channel hot electrons are generated at the drain end of the memory cell 1, and the electrons are trapped at the drain end of the ONO film of the memory cell 1. As a result, the threshold voltage of the memory cell 1 increases from about 2 V in an erased state to about 6 V in a written state.

At this time, the voltage of 1.8 V is applied to the gate of the second select transistor 31, and as described above, a low breakdown voltage transistor having high mutual conductance is used as the second select transistor 31, whereby a sufficient amount of current, e.g., a current of about 100 μA, can flow. Moreover, the voltage of 0 V is applied to the source of the second select transistor 31, and a voltage higher than 1.8 V is not applied to the drain of the second select transistor 31.

Thus, the nonvolatile semiconductor memory device of the example embodiment retains only 1-bit data per memory cell 1. Accordingly, a feature of the nonvolatile semiconductor memory device of the example embodiment is to write only one bit of each memory cell 1 having its drain on the side of the first sub bit line 20 that is driven by the first select transistor 21.

By performing the above procedures, data is written to the memory cells 1 included in the first rewrite sector A and the second rewrite sector B. The first sub bit lines 20 connected to the memory cells 1 included in the first rewrite sector A are electrically isolated from the second rewrite sector B by the first select transistors 21. Thus, in the write operation, the voltage of 5 V, which is applied to the first sub bit line 20 connected to the memory cells 1 to be rewritten in the first rewrite sector A, is not applied to the first sub bit lines 20 in the second rewrite sector B. Accordingly, the state of each memory cell 1 included in the second rewrite sector B does not change when writing the memory cells 1 in the first rewrite sector A. That is, it is ensured that each memory cell 1 in the second rewrite sector B does not change from the erased state to the written state.

(Erase Method)

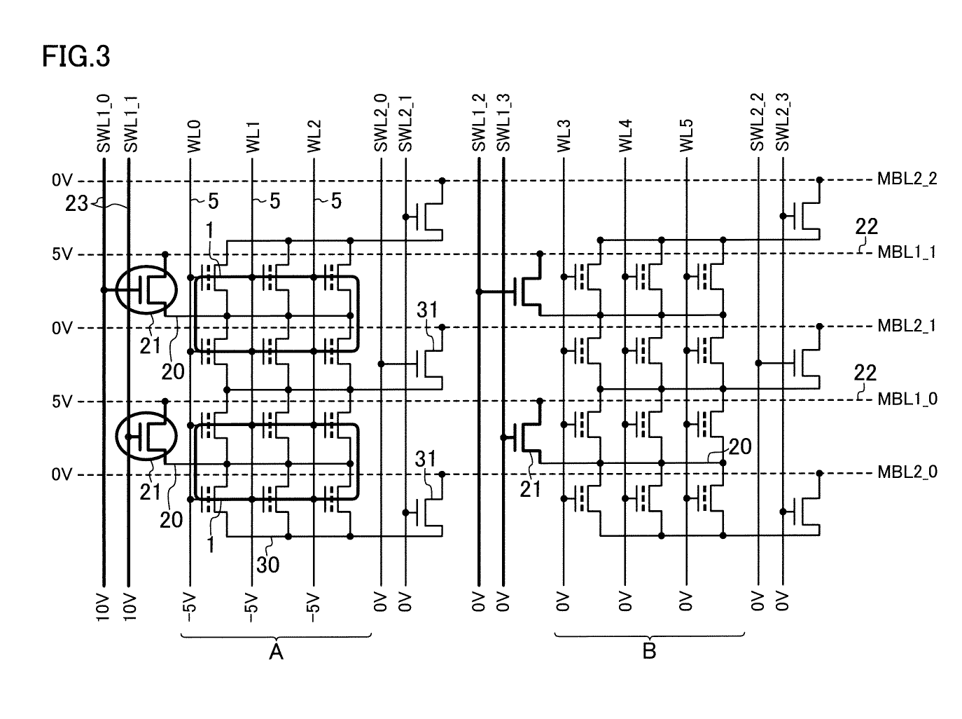

A method of erasing data from the memory cells 1 in the first rewrite sector A will be described below with reference to FIG. 3.

As shown in FIG. 3, the cells to be erased are the circled memory cells 1 connected to WL0 to WL2 of the memory word lines 5. A voltage of −5 V is applied to WL0 to WL2, a voltage of 10 V is applied to SWL1_0 and SWL1_1 of the first select word lines 23, a voltage of 5 V is applied to MBL1_0 and MBL1_1 of the first main bit lines 22, and a voltage of 0 V is applied to the remaining terminals. Thus, the voltage of −5 V is applied to the gates of the memory cells 1, the voltage of 5 V is applied to the drains thereof, and the sources thereof are in an open state. As a result, a band-to-band tunneling current is generated at the drain end of each memory cell 1, and holes are trapped at the drain end of the ONO film of each memory cell 1. Thus, the threshold voltage of each memory cell 1 decreases from about 6 V in the written state to about 2 V in the erased state.

At this time, the voltage of 0 V is applied to the gates of the second select transistors 31, and the second sub bit lines 30 are in an open state. However, since the voltage of 5 V that is applied to the first sub bit lines 20 is not transmitted through the channels of the memory cells 1, a drain voltage of the second select transistors 31 normally does not increase to a potential higher than 1.8 V. However, since the drain voltage of the second select transistors 31 may increase to a potential higher than 1.8 V in some cases, it is preferable to provide a protective element for the second select transistors 31, as described later. This preferred protective element will be described later.

Since only 1-bit data is retained per memory cell 1 in the example embodiment, a feature of the example embodiment is to erase only the bit of each memory cell 1 having its drain on the side of the first sub bit line 20 that is driven by the first select transistor 21.

By performing the above procedures, 1-bit data is erased from each memory cell 1 included in the first rewrite sector A and the second rewrite sector B. The first sub bit lines 20 connected to the memory cells 1 included in the first rewrite sector A are electrically isolated from the second rewrite sector B by the first select transistors 21. Thus, in the erase operation, the voltage of 5 V that is applied to the first sub bit lines 20 connected to the memory cells 1 to be erased is not applied to the first sub bit lines 20 in the second rewrite sector B. Accordingly, the state of each memory cell 1 included in the second rewrite sector B does not change when erasing the memory cells 1 in the first rewrite sector A. That is, it is ensured that each memory cell 1 in the second rewrite sector B does not change from the written state to the erased state.

(Read Method)

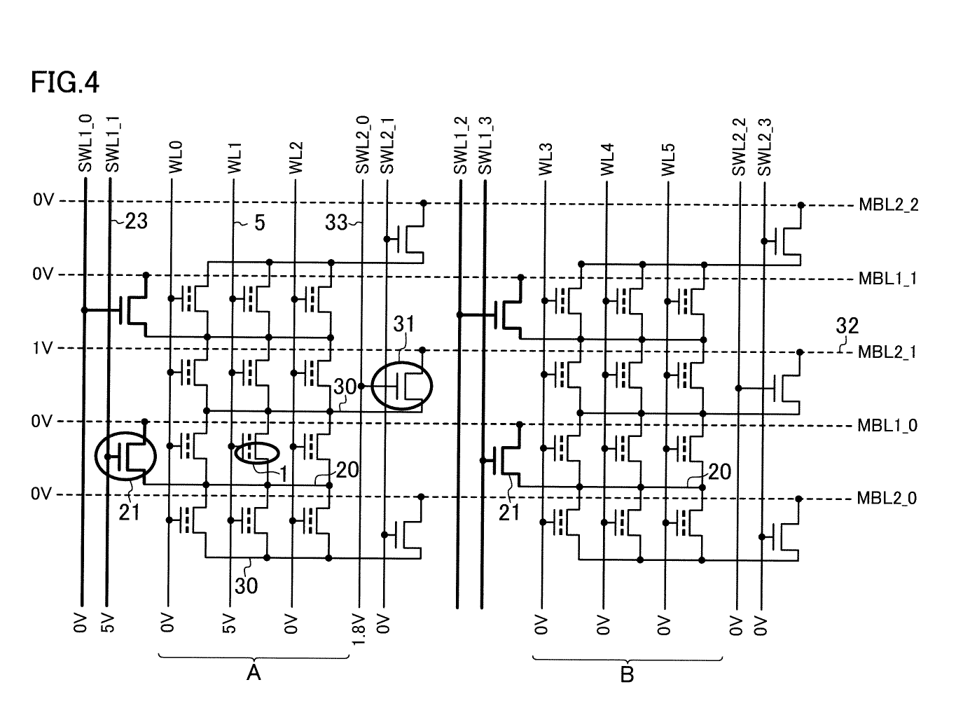

A method of reading data from a cell to be read in the first rewrite sector A will be described below with reference to FIG. 4.

As shown in FIG. 4, the cell to be read is the circled memory cell 1 connected to WL1 of the memory word lines 5. A voltage of 5 V is applied to WL1, a voltage of 5 V is applied to SWL1_1 of the first select word lines 23, a voltage of 1.8 V is applied to SWL2_0 of the second select word lines 33, a voltage of 1 V is applied to MBL2_1 of the second main bit lines 32, and a voltage of 0 V is applied to the remaining terminals. Thus, the voltage of 5 V is applied to the gate of the designated memory cell 1, the voltage of 1 V is applied to the source thereof, and the voltage of 0 V is applied to the drain thereof. As a result, a channel current flows from the source to the drain. Since the channel current that flows in the read operation is about 20 μA in the erased state (the threshold voltage is about 2V), but is less than 1 μA in the written state (the threshold voltage is about 6 V), the retained data can be determined by the channel current.

At this time, the relatively low voltage of 1.8 V is applied to the gate of the second select transistor 31. Since a low breakdown voltage transistor having high mutual conductance is used as the second select transistor 31, a sufficient amount of current, e.g., a current of about 30 μA, can flow.

As described above, in the example embodiment, low breakdown voltage transistors having a breakdown voltage of about 1.8 V are used as the second select transistors 31 for selecting the rewrite sector A, B, etc. This is because limiting the write operation of the MONOS memory cells 1 to 1 bit on their one sides eliminates the need to drive the second select transistors 31 at a voltage higher than 1.8 V in each of the write, erase, and read operations.

Thus, according to the example embodiment, some of the select transistors are replaced with the low breakdown voltage transistors having a smaller size (occupied area), whereby the efficiency of cell layout can be increased. Moreover, the low breakdown voltage transistor has higher mutual conductance Gm than the high breakdown voltage transistor, and thus a large amount of current can be obtained even with a low voltage. Thus, the voltage to be applied to the second select word line 33 in the read operation can be reduced from 5 V to 1.8 V, whereby power consumption can be reduced. Moreover, since the time it takes to increase the voltage of the second select word line 33 to 1.8 V is shorter than the time it takes to increase the voltage of the second select word line 33 to 5 V, the read operation can be performed at a high speed.

(Configuration of Decoder Circuit)

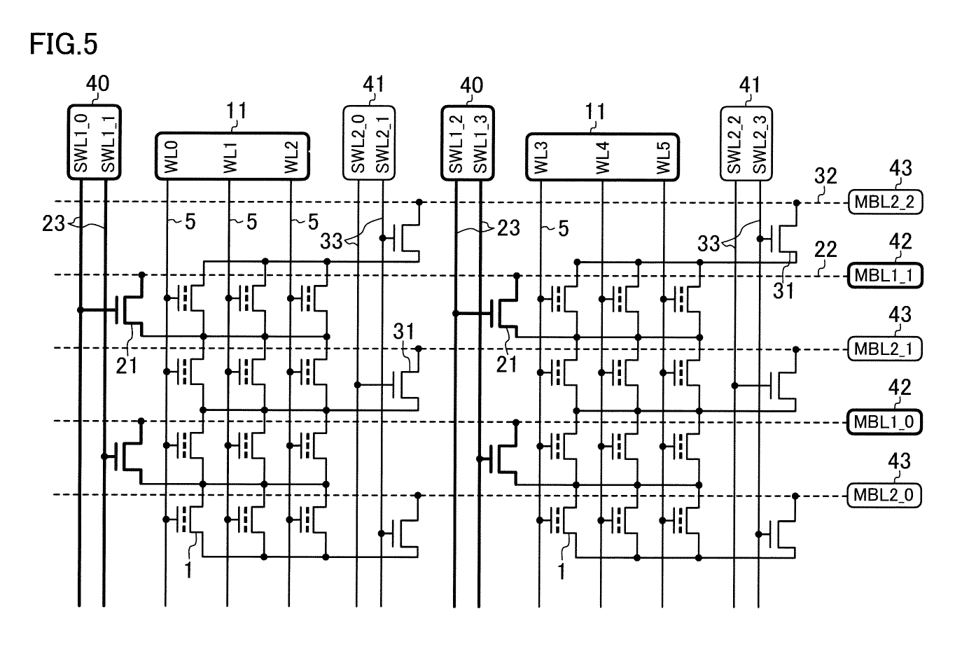

A circuit configuration of a decoder circuit that forms the nonvolatile semiconductor memory device of the example embodiment will be described below with reference to FIG. 5.

As shown in FIG. 5, WL0 to WL5 as the memory word lines 5 are connected to a word line decoder 11. SWL1_0 to SWL1_3 as the first select word lines 23 are connected to a first select word line decoder 40. SWL2_0 to SWL2_3 as the second select word lines 33 are connected to a second select word line decoder 41.

MBL1_0 to MBL1_1 as the first main bit lines are connected to a first main bit line decoder 42, and MBL2_0 to MBL2_2 as the second main bit lines are connected to a second main bit line decoder 43.

In the example embodiment, the second select word line decoder 41 for applying a voltage to the gates of the second select transistors 31 and the second main bit line decoder 43 for applying a voltage to the drains of the second select transistors 31 need only supply a voltage of 1.8 V or less. Thus, low breakdown voltage transistors that are equivalent to the second select transistors 31 can be used as transistors that form the second select word line decoder 41 and the second main bit line decoder 43. This can significantly reduce the areas occupied by the second select word line decoder 41 and the second main bit line decoder 43. Moreover, since the breakdown voltage of the transistors is reduced, power consumption can be reduced, and the read speed can be increased.

(Configuration of Protective Element)

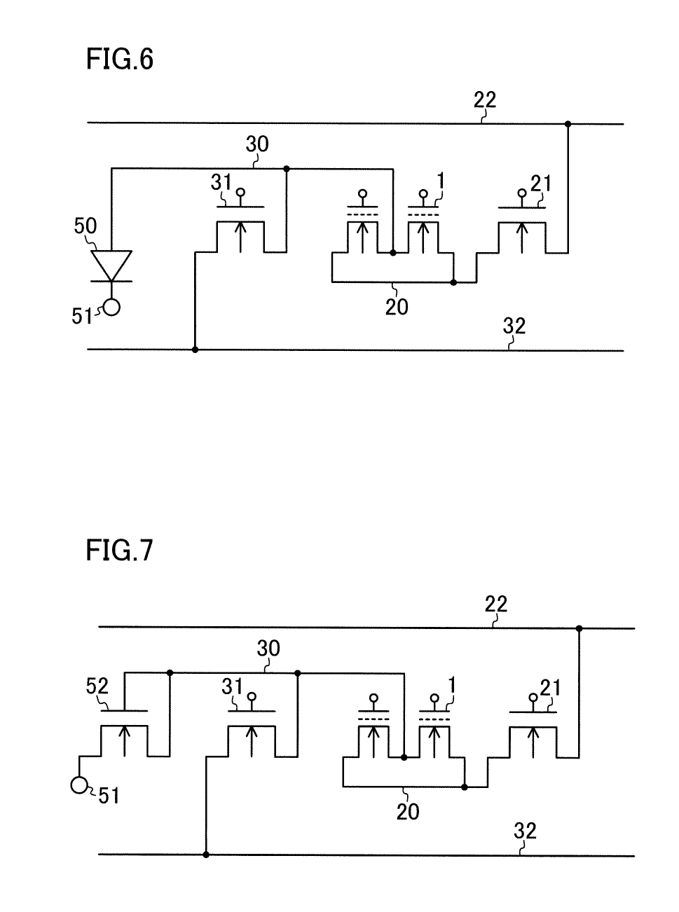

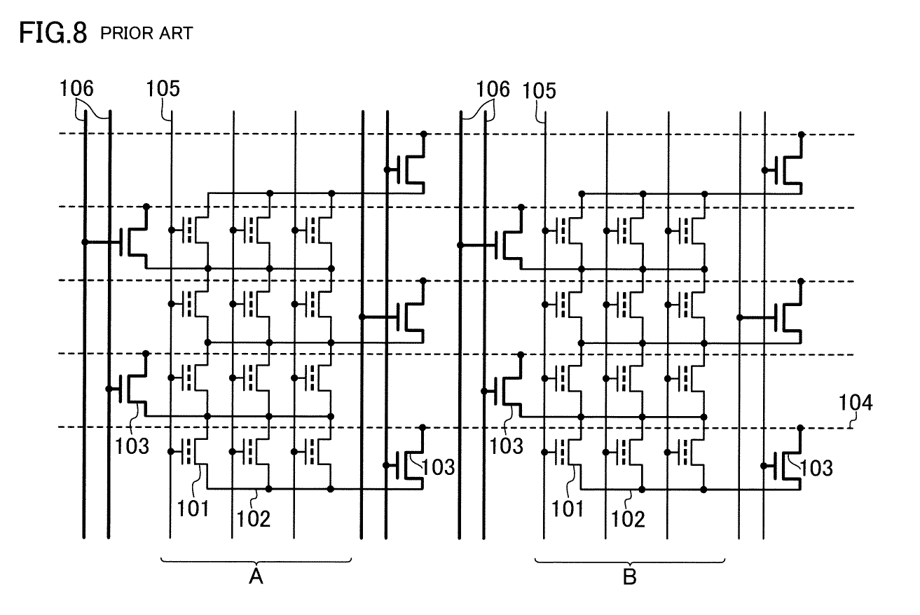

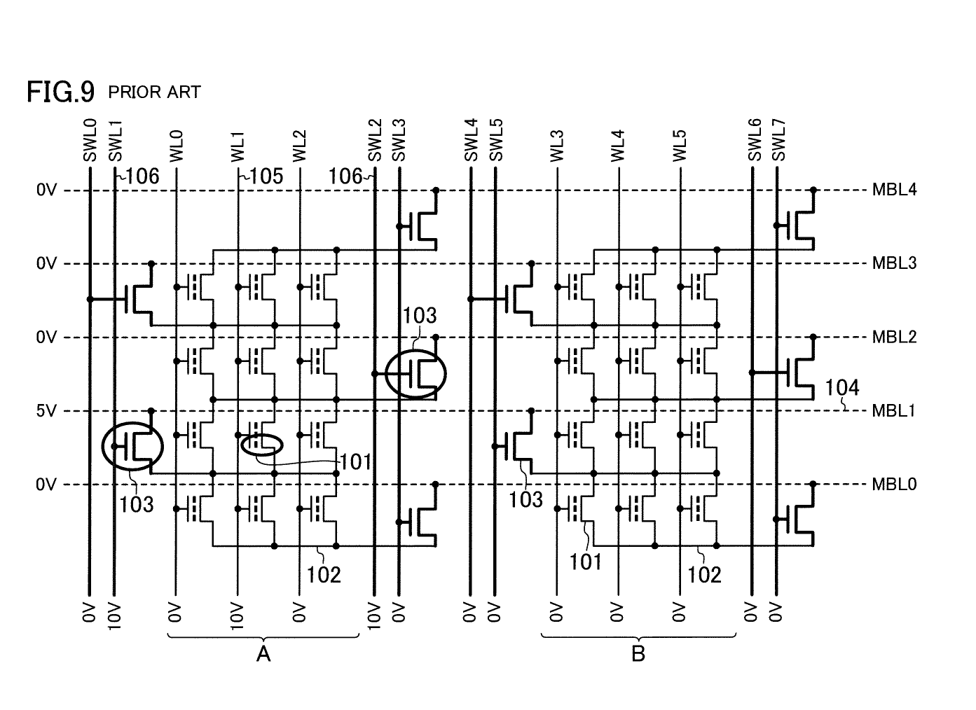

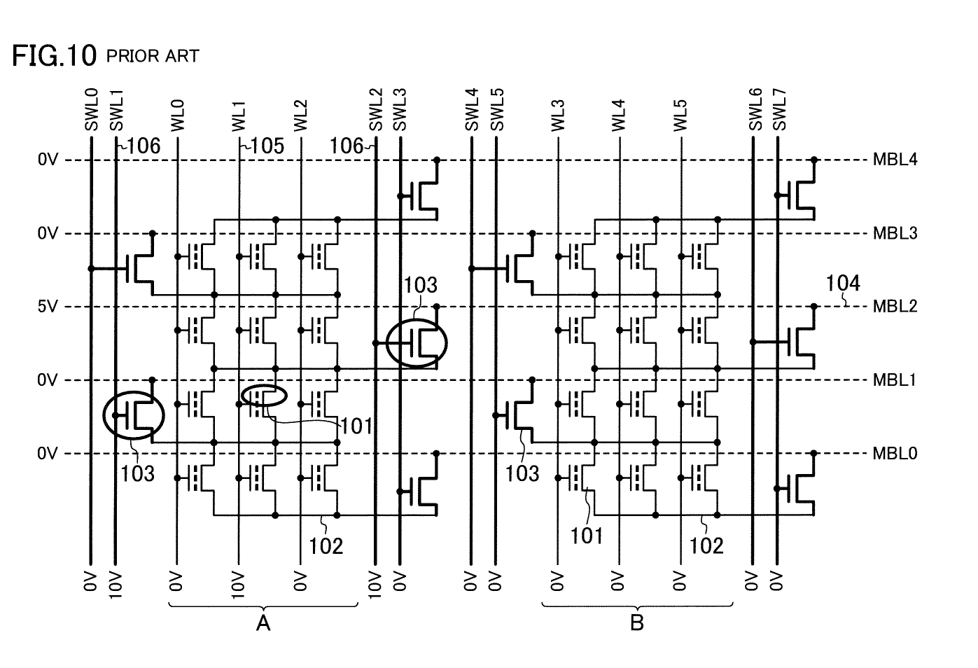

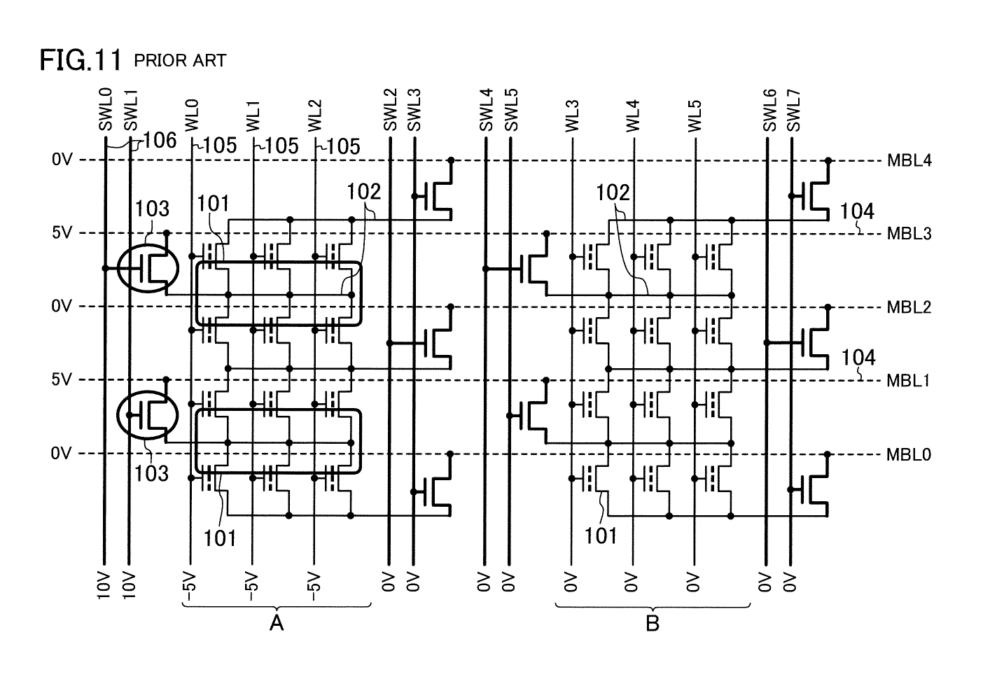

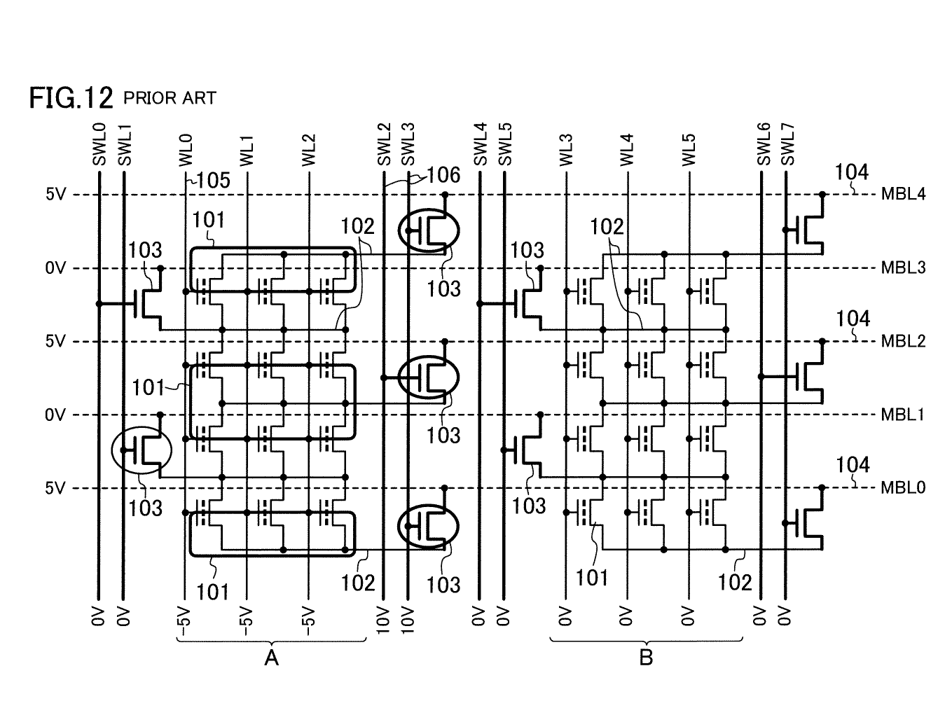

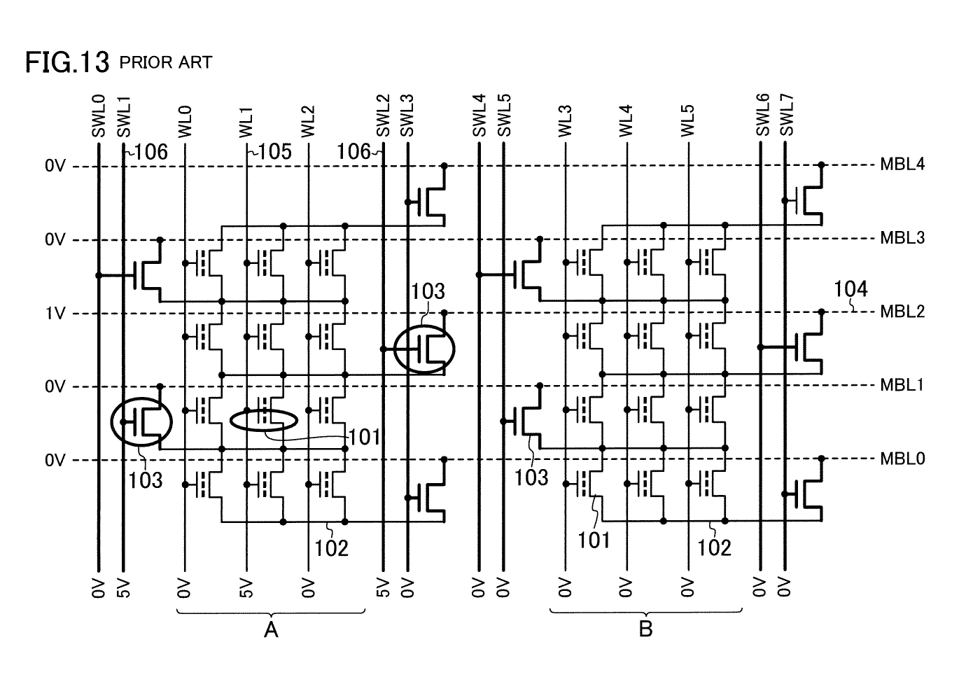

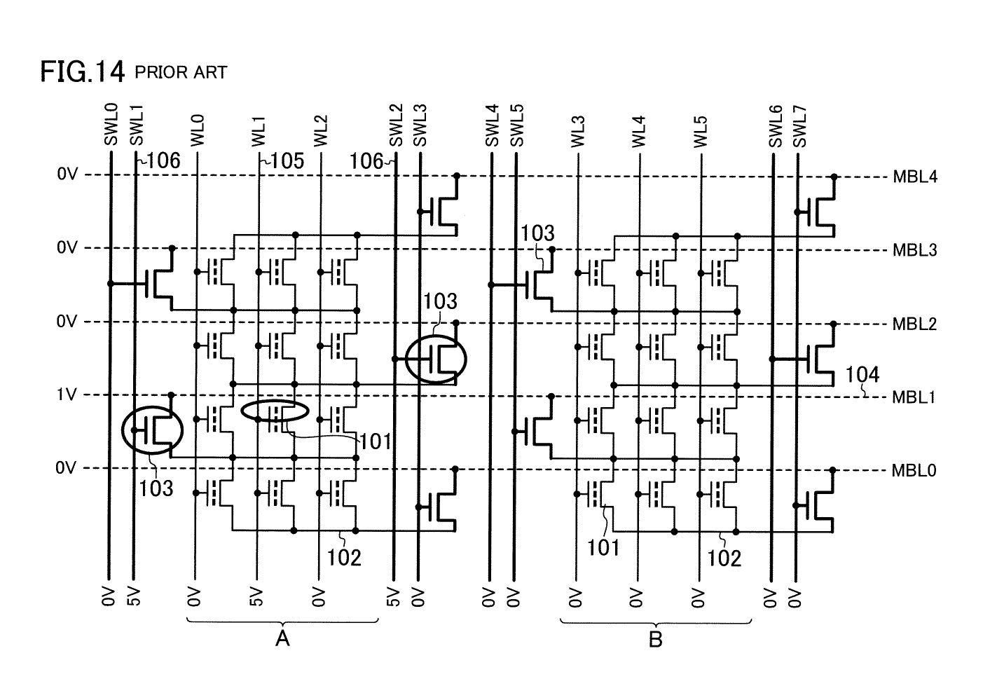

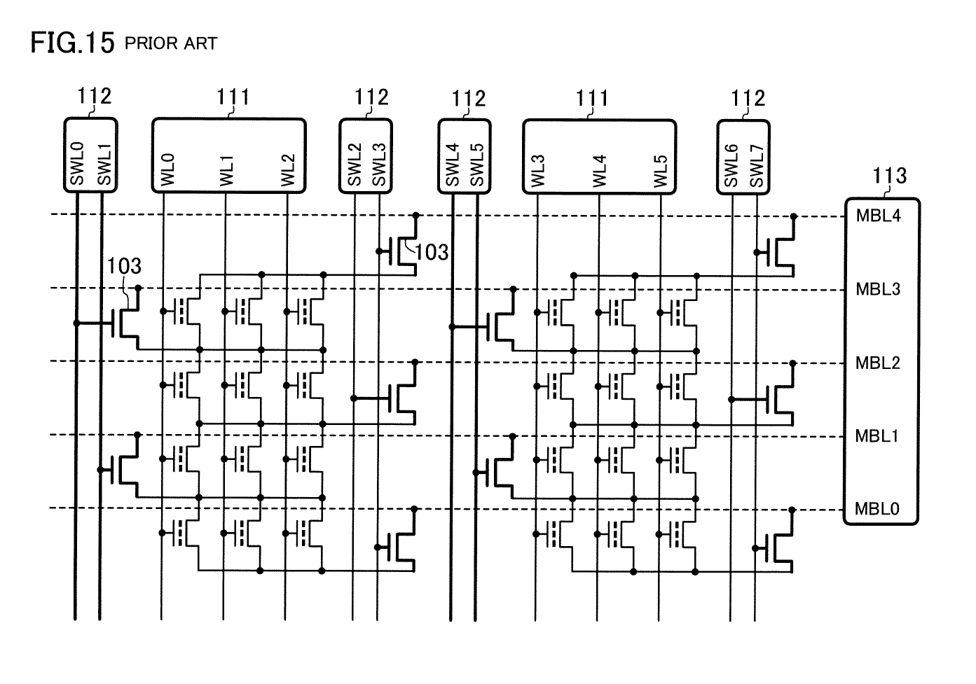

The protective element for the second select transistor 31 according to the example embodiment will be described below with reference to FIGS. 6-7.

As described above, in the erase operation of the memory cell 1, the voltage of 5 V applied to the drain of the memory cell 1 may be transmitted to the source side via the channel of the cell. This is because, even though the voltage of −5 V is applied to the gate, and the channel of the cell is in an off state, a current may flow through the channel due to punch-through. Thus, it is preferable to provide the protective element so that a voltage higher than 1.8 V is not applied to the second sub bit line 30 connected to the drain of the second select transistor 31.

FIG. 6 shows, as a first protective element, a protective diode 50 having its anode connected to the second sub bit line 30 and its cathode connected to a protective control circuit 51 as a control circuit.

In the case where the protective diode 50 is formed by, e.g., an N-type well formed in the semiconductor region and a p⁺ diffusion layer formed in the upper part of the N-type well, the second sub bit line 30 is connected to the p⁺ diffusion layer, and the protective control circuit 51 is connected to the N-type well.

FIG. 7 shows, as a second protective element, a protective metal oxide semiconductor (MOS) transistor 52 formed by an N-type metal oxide semiconductor (NMOS) transistor having its gate and drain connected to the second sub bit line 30 and its source connected to the protective control circuit 51.

In both protective elements, when erasing the memory cell 1, the potential of the N-type well is controlled to the ground potential by the protective control circuit 51 so that a voltage higher than 1.8 V cannot be applied to the second sub bit line 30. When reading the memory cell 1, the potential of the N-type well is controlled to 1.8 V by the protective control circuit 51 so that a potential of 1 V as a read drain voltage can be applied to the second sub bit line 30.

As described above, according to the example embodiment, as shown in FIG. 4, a transistor having a lower breakdown voltage than the first select transistor 21 that operates when writing and erasing the memory cell 1 are used as the second select transistor 31 that operates when reading the memory cell 1. Thus, some of the select transistors can be formed by transistors that occupy a small area. Moreover, since low breakdown voltage transistors can also be used as the transistors of the second select word line decoder 41 and the second main bit line decoder 43 that drive the second select transistor 31 having a low breakdown voltage, the efficiency of cell layout can be increased.

Note that using the low breakdown voltage transistors can reduce the overall area specifically by about 10%, including the transistors in the decoders, although the percentage of the area reduction depends on the array configuration.

In the nonvolatile semiconductor memory device and the driving method thereof according to the present disclosure, the select transistors for the read operation can be replaced with the low breakdown voltage transistors that occupy a small area. Thus, increased efficiency of cell layout, a reduced memory cell area, reduced power consumption, and an increased read speed can be implemented. In particular, the present disclosure is useful for nonvolatile semiconductor memory devices such as a MONOS memory device, driving methods thereof, etc.

What is claimed is:

1. A nonvolatile semiconductor memory device, comprising:
a semiconductor region;
a plurality of charge trapping memory cells formed on the semiconductor region and arranged in rows and columns, and each having a first electrode, a second electrode, and a third electrode;
a plurality of word lines each connecting in common the first electrodes of the plurality of memory cells arranged in a column direction;
a plurality of first sub bit lines each connecting in common the second electrodes of the plurality of memory cells arranged in a row direction;
a plurality of second sub bit lines each connecting in common the third electrodes of the plurality of memory cells arranged in the row direction;
a first select transistor having a gate connected to a first select word line extending in the column direction, a source connected to the first sub bit line, and a drain connected to a first main bit line extending in the row direction; and
a second select transistor having a gate connected to a second select word line extending in the column direction, a source connected to the second sub bit line, and a drain connected to a second main bit line extending in the row direction, wherein
each of the memory cells is capable of retaining 1-bit data, and
the second select transistor has a lower breakdown voltage than the first select transistor.

2. The nonvolatile semiconductor memory device of claim 1, further comprising:
a protective diode having one terminal connected to the second sub bit line, and the other terminal connected to a control circuit.

3. The nonvolatile semiconductor memory device of claim 1, further comprising:
a protective transistor having a gate and a drain both connected to the second sub bit line, and a source connected to a control circuit.

4. The nonvolatile semiconductor memory device of claim 1, wherein
each of the memory cells has a gate insulating film between the semiconductor region and the first electrode, and the gate insulating film is formed by stacking at least a silicon oxide film and a silicon nitride film, and is capable of trapping carriers.

5. A nonvolatile semiconductor memory device, comprising:
a semiconductor region;
a plurality of charge trapping memory cells formed on the semiconductor region and arranged in rows and columns, and each having a first electrode, a second electrode, and a third electrode;
a plurality of word lines each connecting in common the first electrodes of the plurality of memory cells arranged in a column direction;
a plurality of first sub bit lines each connecting in common the second electrodes of the plurality of memory cells arranged in a row direction;
a plurality of second sub bit lines each connecting in common the third electrodes of the plurality of memory cells arranged in the row direction;
a first select transistor having a gate connected to a first select word line extending in the column direction, a source connected to the first sub bit line, and a drain connected to a first main bit line extending in the row direction;
a second select transistor having a gate connected to a second select word line extending in the column direction, a source connected to the second sub bit line, and a drain connected to a second main bit line extending in the row direction;
a first main bit line decoder circuit including a first transistor that supplies a first voltage to the first main bit line; and
a second main bit line decoder circuit including a second transistor that supplies a second voltage to the second main bit line, wherein
each of the memory cells is capable of retaining 1-bit data, and
the second transistor has a lower breakdown voltage than the first transistor.

6. The nonvolatile semiconductor memory device of claim 5, wherein
each of the memory cells has a gate insulating film between the semiconductor region and the first electrode, and the gate insulating film is formed by stacking at least a silicon oxide film and a silicon nitride film, and is capable of trapping carriers.

7. A nonvolatile semiconductor memory device, comprising:
a semiconductor region;
a plurality of charge trapping memory cells formed on the semiconductor region and arranged in rows and columns, and each having a first electrode, a second electrode, and a third electrode;
a plurality of word lines each connecting in common the first electrodes of the plurality of memory cells arranged in a column direction;
a plurality of first sub bit lines each connecting in common the second electrodes of the plurality of memory cells arranged in a row direction;
a plurality of second sub bit lines each connecting in common the third electrodes of the plurality of memory cells arranged in the row direction;
a first select transistor having a gate connected to a first select word line extending in the column direction, a source connected to the first sub bit line, and a drain connected to a first main bit line extending in the row direction;
a second select transistor having a gate connected to a second select word line extending in the column direction, a source connected to the second sub bit line, and a drain connected to a second main bit line extending in the row direction;
a first select word line decoder circuit including a first transistor that supplies a first voltage to the gate of the first select transistor; and
a second select word line decoder circuit including a second transistor that supplies a second voltage to the gate of the second select transistor, wherein
each of the memory cells is capable of retaining 1-bit data, and
the second transistor has a lower breakdown voltage than the first transistor.

8. The nonvolatile semiconductor memory device of claim 7, further comprising:
a first main bit line decoder circuit including a third transistor that supplies a third voltage to the first main bit line; and
a second main bit line decoder circuit including a fourth transistor that supplies a fourth voltage to the second main bit line, wherein
the fourth transistor has a lower breakdown voltage than the third transistor.

9. The nonvolatile semiconductor memory device of claim 7, wherein
each of the memory cells has a gate insulating film between the semiconductor region and the first electrode, and the gate insulating film is formed by stacking at least a silicon oxide film and a silicon nitride film, and is capable of trapping carriers.

10. A method for driving the nonvolatile semiconductor memory device of claim 2, comprising:
outputting a ground potential from the control circuit when erasing the data retained in the memory cells; and
outputting a potential higher than the ground potential from the control circuit when reading the data retained in the memory cells.

11. A method for driving the nonvolatile semiconductor memory device of claim 3, comprising:
outputting a ground potential from the control circuit when erasing the data retained in the memory cells; and
outputting a potential higher than the ground potential from the control circuit when reading the data retained in the memory cells.
